(19) United States
(12) Patent Application Publication
(10) Pub. No.: US 2017/0288421 A1
(43) Pub. Date: Oct. 5, 2017

(54) BATTERY CHARGER WITH GAUGE-BASED CLOSED-LOOP CONTROL

(71) Applicant: Apple Inc., Cupertino, CA (US)

(72) Inventor: Thomas C. Greening, San Jose, CA (US)

(21) Appl. No.: 15/495,298

(22) Filed: Apr. 24, 2017

Related U.S. Application Data
(63) Continuation of application No. 14/323,961, filed on Jul. 3, 2014.

(51) Int. Cl. H02J 7/00

(52) U.S. Cl. CPC H02J 7/0008; G01R 31/3624

(57) ABSTRACT

Systems and methods for power management are disclosed. In an embodiment, a battery charging system includes closed-loop control of a battery charger using a servo target based on measurements taken by a battery gauge.

### BACKGROUND

### Field

Embodiments related to power management and battery charging systems, are disclosed. More particularly, an embodiment related to a battery charging system with closed-loop control of a battery charger using a servo target based on measurements taken by a battery gauge, is disclosed.

### Background Information

FIG. 1 is a schematic view of a typical battery charging system. Battery charging system 100 may include a charger 102 connected to a battery 104. More specifically, a charger 102 may control the conversion of electrical power provided by an external power supply 106 and the delivery of the converted power to battery 104. A charger controller 108 may control a power converter 110 to deliver power directly to an electrical load 111 and to charge the battery, so as to not exceed the capabilities of power supply 106. The power may be delivered through a pass field effect transistor (FET) 112, and charger controller 108 may control the pass FET 112 to adjust a voltage and current fed to battery 104 for charging. Control by charger controller 108 is typically influenced by measurements provided to charger controller 108 by various sensors in charger 102. More specifically, charger 102 generally measures current and voltage within the charger 102, i.e. within the same integrated circuit package for example that contains the controller 108, when delivering current to charge the battery 104. For example, charger 102 may include a charger current sensor 114 to measure the current that is delivered through the pass FET 112 to battery 104. Likewise, charger 102 may include a charger voltage sensor 116 to measure a battery rail voltage at the charger 102. Charger control may also rely on temperature measurements obtained from a charger temperature sensor 118 that is located remotely in the battery 104.

The typical system may also include a battery gauge 120 that is located remotely in the battery 104. The battery gauge uses battery sensors that may be integrated directly at one or more battery cell 128 to sense battery operating parameters. These include sensed battery voltage 122, battery current 124, and battery temperature 126. These measurements are then typically used to infer battery characteristics, such as state of charge, impedance, capacity, time left until fully discharged, etc. More specifically, the measurements made by the battery gauge are typically relied upon to report system characteristics to a user, e.g., through a display icon indicating a state of charge of battery 104.

### SUMMARY

The typical use of the measurements that are made using the charger-side sensing circuitry 114, 116, and the battery temperature sensor 118 to control the charging process may be suboptimal for several reasons. First, since charger sensors provide measurements similar to the measurements made by battery sensors, the charger sensors represent a redundancy in system components. For example, even if battery temperature sensor 118 provides an accurate measurement of battery temperature, it merely duplicates the measurement 126 that is already taken by battery gauge 120, resulting in additional system cost. Second, the measurements made by the charger sensors may not accurately reflect the voltage and current through the battery cell 128 during charging. For instance, since charger voltage sensor 116 measures voltage at a point upstream of connectors and features such as one or more fuse 130 and/or protective FETs 131 that are in the current path leading to battery cell 128, the charger voltage measurement does not accurately reflect the voltage at the battery cell 128, due to voltage drops across the various resistances along the current path. Consequently, the charging time of battery 104 may suffer during constant voltage charging phases, because charger controller 108 must conservatively account for the measurement inaccuracy (when charging the battery 104.) Similarly, since charger side current sensor 114 is typically implemented as a current mirror on pass FET 112, the charger current measurement is also less accurate due to its dependency on factors such as whether pass FET 112 is linear, fully saturated, etc. Accordingly, measurements by charger current sensor 114 may not accurately reflect the current through the battery cell 128 during charging. Thus, typical charging systems may include redundant components that introduce unnecessary complexity and less accuracy into the battery charging control process.

In accordance with an embodiment of the invention, closed-loop control of a battery charging process (in a battery charging system) is achieved by adjusting a power converter to control battery charging, based directly on measurements taken by one or more sensors that are located in the battery, and where a battery controller and a charger controller are working in tandem. The battery controller repeatedly determines or updates a servo target at a first frequency, in accordance with a first feedback control loop algorithm (or process) that has a first bandwidth. The first feedback control loop process may calculate error values, based on comparing a) a desired and predetermined charging profile, with b) one or more of a present battery current, a present battery voltage, a present battery temperature, or an inferred metric such as state of charge or the current divided by the battery capacity that are provided to the battery controller by the battery gauge and its sensors which are located in the battery. Meanwhile, the charger controller is adjusting or updating the power converter as part of a second feedback controller loop, based on calculating the error between a) the servo target (and perhaps one or more other limit values) received from the battery controller and b) the battery rail voltage measured at a power supply rail in the charger that is connected to a terminal of the battery (and that is delivering power from the power converter to the battery.) The charger controller may also be adjusting or updating the power converter based on one or more limits including the input voltage of the power converter, the input current of the power converter, or the duty cycle of the power converter. The second feedback control loop in the charger controller is operating at a second bandwidth, which may be different than the first bandwidth. The charger controller adjusts or updates the power converter at a second frequency, which may be different than (e.g., higher than) the first frequency at which the servo target is being updated. Thus, a closed-loop control scheme may be implemented in which the battery controller repeatedly provides a desired servo target to the charger controller, while the charger controller adjusts the power converter, to achieve the desired servo target.

The charger controller may need to make adjustments to the power converter more frequently than it receives the desired servo target from the battery controller. One or more sensors and sensor circuitry in the battery measure battery characteristics including battery cell voltage and cell current measurements that are fed to the battery controller, to close the first control loop and allow the servo target to be updated so as to achieve a desired charging profile.

The battery controller and charger controller may operate at different bandwidths, when determining the servo target and adjusting the power converter according to the servo target, respectively. For example, the battery controller may be coupled to communicate with a battery gauge, to receive the battery side measurements from the battery gauge at a first rate, e.g., on the order of about once per second and provide a servo target to the charger controller. The charger controller however may need to repeatedly adjust a duty cycle of the switch mode power converter at a second rate that is higher than the first rate (in order to control a switch mode power conversion process that produces the needed voltage on a power supply rail that is connected to a terminal of the battery). For example, the second rate may be at least ten times the first rate, such that the charger controller operates at a much higher bandwidth than the battery controller. By way of example, whereas the first rate may be on the order of 1 Hz, the second rate may be on the order of more than 100 kHz, e.g., about several hundred kHz.

In an embodiment, a method performed by a battery charging system includes measuring, by one or more sensors and/or sensor circuitry in a battery, at least one of a battery current, a battery voltage, a battery temperature, or an inferred metric such as state of charge or the battery current divided by the battery capacity of a battery bank or cell in the battery. The method may further include repeatedly updating, by a battery controller that is coupled with the one or more sensors, a variable servo target in accordance with a first feedback control loop process that is based on the measured battery side current, battery side voltage, battery side temperature, or inferred metric such as state of charge or the battery current divided by the battery capacity. Determining the servo target may include determining a profile voltage target and a profile current target based on a predetermined or stored charging profile, and comparing the measured battery voltage to the profile voltage target and the measured battery current to the profile current target to determine an error. The servo target may then be determined based on the error in accordance with the first feedback control loop process. The method may further include repeatedly adjusting, by a charger controller, a power conversion circuit that produces voltage on a power supply rail that is connected to a terminal of the battery, wherein the produced voltage is in accordance with a second feedback control loop process that is based on the servo target. Each of the feedback control loop processes may include a proportional-integral-derivative (PID) control scheme having for example zero-value proportional gain and derivative gain terms.

In an embodiment, a battery charging system and method prevents integral wind-up in the PID control scheme. The charger controller may be configured to provide a notification to the battery controller when any target other than the battery voltage rail is limiting the control of the power converter. For example, a method may include determining whether the second feedback control loop process is limited by an input voltage of the power converter, an input current of the power converter, or a duty cycle of the power converter. When the input voltage, the input current, or the duty cycle limits the second feedback control loop, the charger controller may send a notification to the battery controller. In response to the notification, the battery controller may be configured to discontinue its repeated determining or updating of the servo target to prevent a so-called windup condition.

In an embodiment, a battery charging system and method incorporates a lower cost, lower precision digital to analog conversion (DAC) circuit for producing the battery rail voltage set point, where such inaccuracy can be tolerated at the charger controller, because of the servo control being implemented by the battery controller and its accurate measurements. For instance, in one embodiment, the servo target variable may have “lower granularity”, i.e., it can take on fewer discrete values with greater spacing between adjacent values. Now, if it is desired to improve the accuracy of the charger control loop in such a case, the battery rail voltage set point may be dithered around the servo target, while the output of the DAC is low pass filtered to remove the frequency component caused by the dithering.

In an embodiment, a battery charging system and method as described above may eliminate redundancy in system components. For example, the pass field effect transistor (FET) 112 in the conventional charger 102 depicted in FIG. 1 can be removed, because a FET switch that is in line with the current path to the battery and that may be integrated in the battery can be coupled to be controlled by the battery controller. A method may include opening the FET switch circuit to disable charging of the battery, when the battery is fully charged. Thus, the battery charging system may not require an additional pass FET in the charger to disable the charging.

Embodiments may also include non-transitory, computer-readable media having computer-readable instructions for controlling a battery charging process. For example, instructions may cause a battery charging system to implement the methods described above.

The above summary does not include an exhaustive list of all aspects of the present invention. It is contemplated that the invention includes all systems and methods that can be practiced from all suitable combinations of the various aspects summarized above, as well as those disclosed in the Detailed Description below and particularly pointed out in the claims filed with the application. Such combinations have particular advantages not specifically recited in the above summary.

### BRIEF DESCRIPTION OF THE DRAWINGS

FIG. 1 is a schematic view of a typical battery charging system.

FIG. 2 is a schematic view of a battery charging system having a charger in communication with a battery in accordance with an embodiment of the invention.

FIG. 3 is a schematic view of a battery charging system having closed-loop control in accordance with an embodiment of the invention.

FIG. 4 is a graphical view of a battery charging system current versus time in accordance with an embodiment of the invention.

FIG. 5 is a graphical view of a battery charging system voltage versus time in accordance with an embodiment of the invention.

FIG. 6 is a schematic view of a battery charging system having a digital-to-analog converter in accordance with an embodiment of the invention.

FIG. 7 is a pictorial view of an electronic device having a battery charging system in accordance with an embodiment of the invention.

FIG. 8 is a schematic view of an electronic device having a battery charging system in accordance with an embodiment of the invention.

### DETAILED DESCRIPTION

Embodiments of the invention are battery charging systems for use in electronic devices powered by batteries. While some embodiments are described with specific regard to integration within portable electronic devices, the embodiments are not so limited, and certain embodiments may also be applicable to other uses. For example, one or more of the embodiments described below may be integrated within devices or apparatuses that are powered by batteries, regardless of whether the devices or apparatuses typically operate at a single location.

In various embodiments, description is made with reference to the figures. However, certain embodiments may be practiced without one or more of these specific details, or in combination with other known methods and configurations. In the following description, numerous specific details are set forth, such as specific configurations, dimensions, and processes, in order to provide a thorough understanding of the embodiments. In other instances, well-known processes and manufacturing techniques have not been described in particular detail in order to not unnecessarily obscure the description. Reference throughout this specification to “one embodiment,” “an embodiment”, or the like, means that a particular feature, structure, configuration, or characteristic described is included in at least one embodiment. Thus, the appearance of the phrase “one embodiment,” “an embodiment”, or the like, in various places throughout this specification are not necessarily referring to the same embodiment. Furthermore, the particular features, structures, configurations, or characteristics may be combined in any suitable manner in one or more embodiments.

In an aspect, an embodiment of a battery charging system includes closed-loop control of a charging process based on measurements taken in a battery. A battery gauge may measure characteristics of a battery, e.g., cell current, cell voltage, and/or cell temperature, using sensor circuitry in the battery and provide those measurements to a battery controller. The battery controller may use these measurements, inferred metrics (e.g., state of charge or the battery current divided by the battery capacity to a battery controller), and/or charging profile information to determine a servo target. For example, the battery charger may implement a feedback control loop process based on a comparison between at least one target value of a charging profile and the received measurements to repeatedly update the servo target at a first rate. The servo target may be updated to drive an error signal between the received measurements and one or more target values of the charging profile, e.g., target voltage or target current, toward zero. In this way, the servo target may be used to control the charging of the battery to one or more target values as determined by a charging profile. For example, if a charging profile sets a target charging voltage, the servo target may be modified until the cell voltage measured by battery gauge reaches the target charging voltage.

The servo target may be provided to a charger controller as a set point to control a battery charger to provide a desired voltage to the battery during charging. For example, the charger controller may repeatedly adjust a power converter of the battery charger at a second rate different than the first rate to maintain a desired output based on the servo target. For example, in some variations the charger controller may adjust the power converter to maintain a desired target output voltage based on the servo target, while the current can vary as system loads change. The power provided to the battery during charging may be measured by the battery gauge and fed back to the battery controller to close the control loop and update the servo target, if necessary. Since the servo target is determined based on accurate measurements taken in the battery, the closed-loop control may allow for more precise charging control and may lead to faster charging times. Furthermore, since the servo target may be based on measurements taken in the battery rather than the charger, the need for charger side sensor circuitry to measure charging parameters may be reduced. Thus, closed-loop control may reduce system circuitry and an overall system design may be simplified to reduce overall system cost.

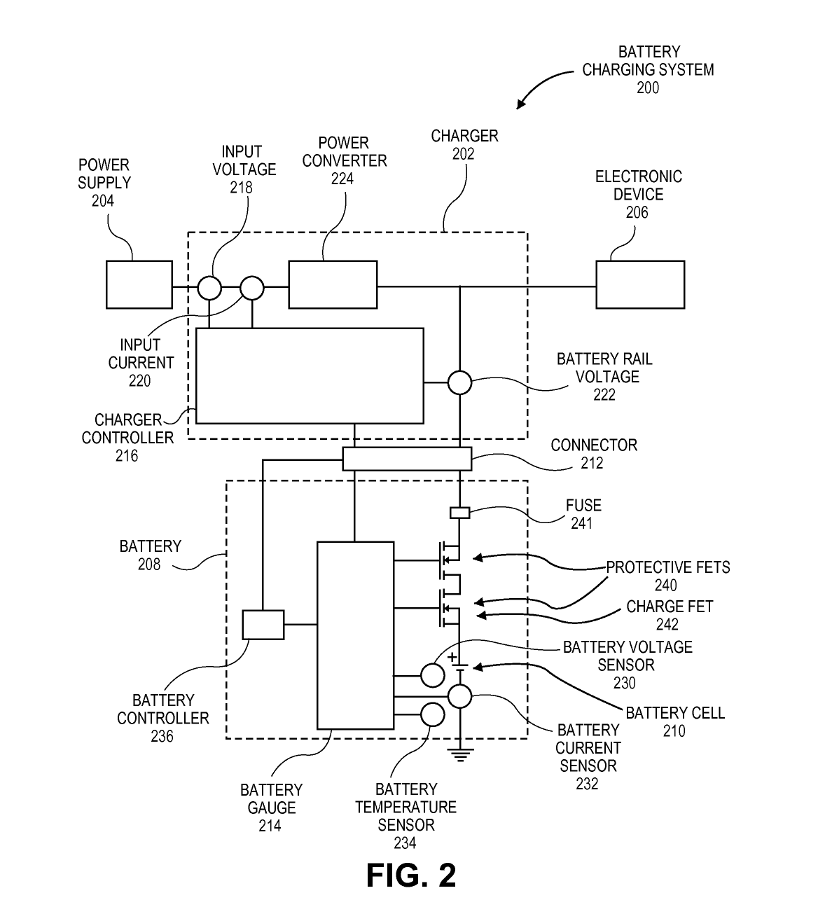

Referring to FIG. 2, a schematic view of a battery charging system having a charger in communication with a battery is shown in accordance with an embodiment of the invention. In one embodiment, the battery charging system 200 includes a charger 202 electrically coupled with a battery 208. More particularly, the charger 202 may be electrically connected between a power supply 204, one or more functional components of an electronic device 206, and battery 208. Charger 202 may receive power from an external power supply 204, such as an AC wall adapter, a laptop computer, a desktop computer, another USB compatible host, or a wireless power receiver. Charger 202 may subsequently provide the power received from power supply 204 to power the electronic components of electronic device 206, and to charge one or more battery cells 210 in battery 208. Electronic device 206 may also include power control elements separate from charger 202, such as an electronic voltage regulator within electronic device 206 physically separated from charger 202.

The elements of battery charging system 200 may be packaged in various manners. For example, battery 208, charger 202, and the other electronic components of electronic device 206 may be co-located within a same enclosure that is physically recognized as the electronic device 206, e.g., as a mobile phone device or a laptop computer. Alternatively, battery 208 and charger 202 may be co-located in an enclosure that is physically separated from, but electrically connected with, an electronic device 206 enclosure. Thus, the elements of battery charging system 200 may occupy respective spatial volumes at separate physical locations, yet be electrically connected to form a system having the characteristics described below.

Connections between the components of battery charging system 200, and between battery charging system components and external components, may be made using one or more known electrical connectors, such as pins, leads, vias, contacts, wires, ribbon cables, etc. Connections may be used for power transfer or communications. For example, charger 202 may be electrically coupled with battery 208 through a connector 212. Connector 212 may transfer electrical current from a battery rail of charger 202 to charge battery cell 210. Additionally, connector 212 may provide for data communications between battery 208 and charger 202. More specifically, connector 212 may provide a communications path to allow information to be communicated directly between one or more of a battery gauge 214, a battery controller 236, and a charger controller 216. Battery gauge 214 may be incorporated in, or located away from, battery 208. For example, battery gauge 214 may reside on a circuit board that is packaged in a same enclosure as one or more battery cell 210. Alternatively, battery gauge 214 may be packaged or located separately from the enclosure holding one or more battery cell 210, but may nonetheless be electrically connected to battery sensors residing inside of the enclosure holding the one or more battery cell 210.

Battery controller 236 and charger controller 216 may include analog or digital circuitry configured to implement one or more functions, such as PID control processes. Thus, the designation of the controllers as being associated with a “battery” or “charger” are not intended to imply a specific location or packaging of the circuitry. For example, battery controller 236 circuitry and charger controller 216 circuitry may be packaged together. Indeed, battery controller 236 and charger controller 216 may be implemented within a same controller hardware, e.g., by a same microcontroller that is programmed to simultaneously implement a plurality of feedback control loop processes, such as those described below.

In an embodiment, charger controller 216 controls how much power is transferred from the power supply 204 to feed a battery rail. To do so, charger controller 216 may adjust a power converter 224 having an input connected to power supply 204 and an output connected to battery rail voltage 222. For example, the power converter 224 may be a switch mode converter and accordingly, the charger controller 216 may adjust a duty cycle of the power converter 224 to control how much power is transferred from the input to battery rail voltage 222. Voltage and current limits for the input power to a power converter 224 may vary based on the type of power source, e.g., whether power supply 204 is a powered hub or an unpowered hub. Thus, the input voltage 218 and input current 220 are measured by the charger controller 216 for use during charger control, e.g., to adjust the power converter 224 to prevent exceeding target limits for input voltage 218 and input current 220. Furthermore, the battery rail voltage 222 may be sensed and input to charger controller 216 to control power delivery by the power converter 224. For example, charger controller 216 may adjust the power converter 224 to control the battery rail voltage 222 to the servo target as the loads of the electronic device 206 vary. In this way, voltage and current delivered to a terminal of battery 208 may be adjusted by altering battery rail voltage 222. In an embodiment, power converter 224 is a DC-to-DC converter, such as a linear voltage regulator, a switched-mode converter, etc. More particularly, power converter 224 may be a buck, boost, or buck-boost converter. For example, power converter 224 may be a buck converter to reduce a direct current input voltage 218 to a direct current battery rail voltage 222.

Charger controller 216 may be located at any suitable location. For example, charger controller 216 may be packaged as part of charger 202, e.g., within a same enclosure or on a same circuit board as other charger 202 components. Alternatively, charger controller 216 may be packaged outside of an enclosure or circuit board having other charger 202 components. Thus, charger controller 216 may be located at any suitable location to implement the functionality described below. For example, charger controller 216 may include circuitry configured to implement a PID controller used to, e.g., adjust a power converter of the battery charger. In some instances, the charger controller 216 may be an analog circuit. For example, charger controller 216 may include an analog PID controller using an op-amp with resistive and capacitive feedback to set the P and I gains in the PID process. Alternatively, it is possible for charger controller 216 to include a digital controller, such as a microcontroller, that implements a PID control algorithm. Accordingly, charger controller 216 may include a processor, and the processor may also execute instructions to carry out different functions and applications of electronic device 206. For example, charger controller 216 may be implemented as an internal subsystem of electronic device 206 that is physically separate from charger 202. Regardless of its physical implementation, charger controller 216 may perform the operations described below in connection with controlling battery charging processes.

As mentioned above, battery 208 includes one or more battery cells 210. The one or more battery cells 210 may form a battery pack. In an embodiment, battery 208 includes a battery pack having one or more battery banks in series. Furthermore, each battery bank has a set of one or more battery cells in parallel, which may be treated as a single unit. For example, in some variations the battery 208 may include a plurality of battery banks. In some of these variations, at least one of the plurality of battery banks comprises a plurality of battery cells in parallel. Battery 208 may also include one or more sensors to sense voltage, current, or temperature of a battery cell, a battery bank, or a battery pack. The cell, bank, or pack may be measured individually or in combination. For example, one or more sensors may be integrated in battery 208 to directly sense one or more of a current, a voltage, or a temperature of battery cell 210. The sensed parameters may be measured by battery gauge 214, which may be connected to the one or more sensors.

In an embodiment, one or more battery voltage sensor 230 may be used to measure one or more voltages within battery 208. For example, each battery voltage sensor 230 may be integrated in battery 208 to directly measure voltage of one or more battery cell 210. In an embodiment, each battery voltage sensor 230 measures voltage of a single respective battery cell 210. Alternatively, one or more battery voltage sensor 230 may measure the overall voltage applied to multiple battery cells 210, e.g., one battery voltage sensor 230 may measure voltage applied to a battery bank (which measures the voltage of each cell in instances where there are multiple cells in parallel). Further, one or more battery voltage sensor 230 may be used to measure the overall voltage applied to one or more battery banks, e.g., a plurality of sensors may measure respective battery bank voltages in the case where there are multiple battery banks in series or a single sensor may measure the voltage across the entire battery pack. In an embodiment, battery voltage sensor 230 includes a Kelvin connection placed across the cell, bank, or pack of interest in battery 208. Typically, a Kelvin connection can measure voltage with an accuracy of about 1 mV or better; however other voltage sensor types may be used as desirable. Thus, each battery voltage sensor 230 may be placed across one or more battery cells 210 to accurately measure voltage in battery 208.

In an embodiment, a battery current sensor 232 is integrated in battery 208 to directly measure current within battery 208. For example, battery current sensor 232 may include a sense resistor, such as a low temperature-coefficient sense resistor, placed in series with battery cell 210 to measure current flowing through battery cell 210. The voltage across the sense resistor may be measured to provide an accurate measurement of battery current. For example, the sense resistor may be a 5-10 mΩ resistor, and voltage across the resistor may be measured with an operational amplifier and an analog-to-digital converter to measure current. The accuracy of a current measurement obtained using a sense resistor can be substantially higher than the accuracy provided by measuring current using, e.g., a current mirror on a pass FET in charger 202, because the sense resistor measurement may not depend on factors such as whether the pass FET is linear, fully saturated, etc. Although a sense resistor may provide high accuracy current measurements, other current sensors may be used as desirable. Additionally, placing the current sensors directly in battery 208 may allow for multiple current sensors to be used to sense current through portions of battery 208, e.g., through individual battery cells 210 of a battery bank. Thus, battery current sensor 232 may be placed within battery 208 to directly and accurately measure current through one or more battery cell 210 in battery 208.

In an embodiment, a battery temperature sensor 234 is integrated in battery 208 to directly measure temperature within battery 208. For example, battery temperature sensor 234 may include one or more thermistors placed near one or more battery cell 210. The thermistor may be calibrated in a factory and located directly adjacent to the battery cells 210 to ensure highly accurate measurements. Although a thermistor provides high accuracy, other temperature sensors may be used as desirable. Thus, battery temperature sensor 234 may be placed within battery 208 to directly measure temperature of one or more battery cell 210 in battery 208.

Battery 208 may further include a battery controller 236 to receive measurement signals from the battery sensors, e.g., via battery gauge 214, and to process the received signals to provide various functionality. Battery controller 236 may be physically integrated within battery gauge 214, or it may be physically separated from battery gauge 214 as shown in the FIG. 2. Accordingly, battery controller 236 may be a microcontroller that is typically part of battery gauge 214, or it may be a separate microcontroller used to implement specific functionality. For example, battery controller 236 may be implemented as an internal subsystem of an electronic device 206 that is outside of the battery. In an embodiment, battery controller 236 may be any processor that executes instructions to carry out different functions and applications of electronic device 206. Battery controller 236 may be programmed to perform the operations described below in connection with controlling battery charging processes.

As mentioned above, battery controller 236 may provide one or more outputs that may be used by charger controller 216. The outputs may be communicated between the controller circuitry in a variety of manners. For example, outputs from battery controller 236 may be communicated to charger controller 216 without passing through intermediate circuitry, i.e., an output pin of battery controller 236 may be connected to an input pin of charger controller 216 by an electrical lead. Alternatively, outputs from battery controller 236 may be relayed to charger controller 216 through circuitry of at least one other component, such as through a communication interface circuitry of battery gauge 214 or connector 212, or through a digital-to-analog converter as described below. Communications between gauges and controllers of charger 202 and battery 208 may be using any suitable bus protocol, e.g., System Management Bus (SMB). Thus, battery charging system 200 may have components that communicate to implement a closed-loop servo control of the charging process.

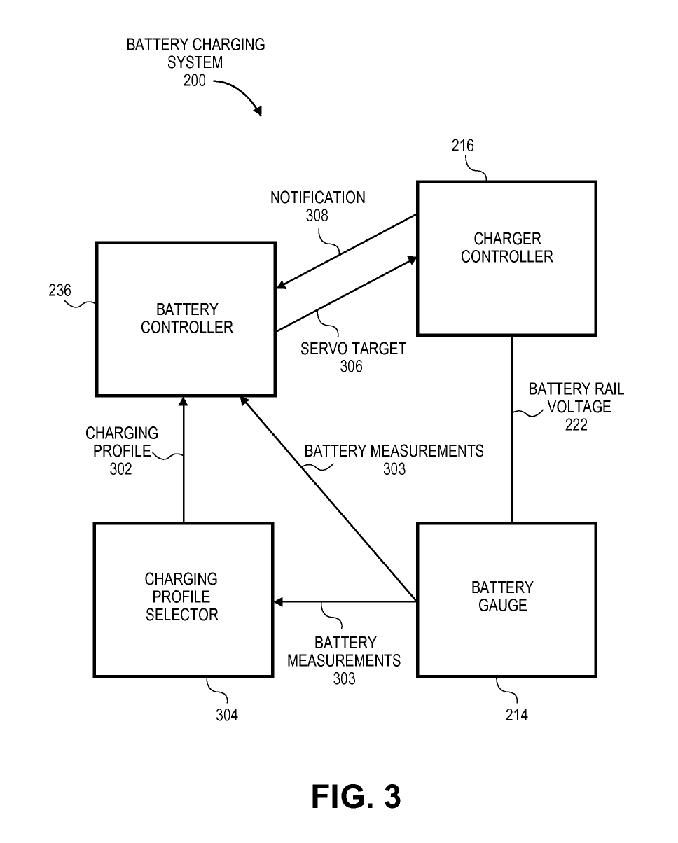

Referring to FIG. 3, a schematic view of a battery charging system having closed-loop control is shown in accordance with an embodiment of the invention. In an embodiment, battery charging system 200 implements closed-loop control of the charging process based on measurements taken in the battery 208, e.g., at battery cell 210. In an embodiment, battery controller 236 may implement a first feedback control loop process to periodically determine a servo target 306 based on input measurements 303 taken using one or more of sensors 230, 232, or 234 in the battery 208 or using inferred metrics such as state of charge calculated by the battery gauge 214. More particularly, servo target 306 may be periodically determined based on a comparison between the input measurements/metrics and one or more target values of a charging profile. Charger controller 216 may receive the repeatedly updated servo target 306 and use the servo target 306 as a set point in a second feedback control loop process to repeatedly adjust a charger such that an output battery rail voltage 222 connected to a terminal of the battery 208 is maintained at a desired level corresponding to servo target 306. More particularly, battery rail voltage 222 may be controlled such that the battery measurements 303 taken by the battery gauge 214 and reported to the battery controller 236 meet a desired charging profile 302.

Battery controller 236 may implement a first feedback control loop process, such as a proportional-integral-derivative (PID) control scheme, to determine servo target 306 based on one or more target values of a charging profile 302 and one or more measurements 303 of battery voltage, battery current, or battery temperature, taken by battery gauge 214 from battery sensors 230, 232, and 234 or an inferred metric such as state of charge calculated by the battery gauge 214. The charging profile 302 may be provided to battery controller 236 by a charging profile selector 304. More particularly, charging profile selector 304 may receive one or more battery measurements 303 or inferred battery metrics from battery gauge 214 to determine a charging profile 302 to be used by battery controller 236 in determining or updating servo target 306. The charging profile 302 may provide one or more target values for one or more measurements 303 taken by the battery gauge 214. In an embodiment, the charging profile selector 304 repeatedly updates the charging profile 302 and/or the one or more target values of the charging profile 302, at a rate. The rate may be independent of the rate the servo target is determined. For example, in some variations, the charging profile selector 304 may determine the charging profile 302 at a rate that is less than or equal to the rate the servo target is determined. In some of these variations, the charging profile selector 304 may determine the charging profile 302 at a rate that is greater than the rate that the servo target is determined. Accordingly, charging profile selector 304 may be implemented in the battery charging system 200 as circuitry, e.g., digital electronics, which are part of, or separate from, the battery controller 236 or the battery gauge 214.

Numerous charging profiles 302 may be implemented by charging profile selector 304. By way of example, charging profile selector 304 may select a charging profile 302 for a given battery temperature range and a charge state of battery 208, and the selected charging profile 302 may be fed to battery controller 236 as a profile voltage target and a profile current target at any time during the charging process. An example of a charging profile 302 is described in U.S. Pat. No. 8,624,560, titled “Controlling Battery Charging Based on Current, Voltage, and Temperature”, filed on Jun. 8, 2009, which is incorporated herein by reference. Other profile examples include adaptive surface concentration charging (ASCC), which helps avoid lithium surface saturation during the charging process of lithium polymer batteries. In general, any known or suitable charging profile 302 may be implemented by charging profile selector 304 to compute a profile target voltage and a profile target current, as well as accompanying voltage and current limits. Those targets and limits may then be provided to battery controller for use in a feedback control loop process to determine servo target 306.

Servo target 306 may be determined by battery controller 236 using a proportional-integral-derivative (PID) control scheme. In an embodiment, voltage and current may be monitored as process variables by a battery gauge 214 connected to battery voltage sensor 230 and battery current sensor 232. The voltage and current measurements 303 may be very accurate, since the measurements may be made within battery 208 directly at battery cell 210, as described above. To determine an error signal for PID control, the measured voltage and current values 303 may be compared to the profile target voltage and profile target current of charging profile 302. The difference between the set points, i.e., the profile targets, and the measured process variables, i.e., the measured values 303, may provide an error term for each process variable. These error terms may be computed by battery charger 236 for each battery cell and battery bank in battery 208.

In an embodiment, battery controller 236 implements a control scheme that controls the process variable having the lowest error, e.g., an error value of zero. At a given time, one of the profile target values, e.g., the target voltage or the target current, may equal a corresponding measured value, e.g., the profile target voltage may equal the measured voltage from battery voltage sensor 230. At that time, the difference between the profile target voltage value and the measured voltage value is zero. However, at the same time, the profile target current value may be below the measured current value. That is, the battery voltage may be at the desired level but the battery current may still be approaching the desired level indicated by the charging profile 302. During this time, the control scheme may control the process variable with the lowest error, i.e., the battery voltage, while the other process variable, i.e., the battery current, approaches the desired level. However, once the other process variable reaches the desired level, it may then have an associated error of zero, and the charging profile 302 may implement a new desired level for the first process variable, i.e., the battery voltage, at which point the control scheme will control battery current since it will have the lowest error until battery voltage again reaches its associated desired level. This method of sequentially controlling the process variables may be continued until battery 208 reached a full state of charge.

In an embodiment, having calculated an instantaneous error for the variable of interest, i.e., a difference between a target and measured value for the process variable having the lowest error, battery controller 236 may calculate servo target 306. The instantaneous error may be introduced into a PID control algorithm having one or more of a proportional term, an integral term, and a derivative term. The terms may incorporate respective gains, or tuning parameters, as is known in the art. For example, the proportional term multiplies the error by a constant proportional gain, and thus, produces an output value that is proportional to the error value. The integral term is the sum of instantaneous errors over time and includes a constant integral gain multiplied by the accumulated error. The derivative term is calculated by determining the rate of change of instantaneous errors over time and multiplying the rate of change by a constant derivative gain. PID control algorithms and variations of such algorithms are known in the art, and thus, further discussion of the various control methodologies that are within the scope of this description shall not be given further treatment here. As a result, the PID control scheme implemented by battery controller 236 may calculate servo target 306.

Servo target 306 may correspond to a set point for a measured process variable on the charger 202 side. For example, servo target 306 may correspond to a desired battery rail voltage 222 that will maintain the measured variable of interest on the battery 208 side at the target level. That is, in a case where the battery controller 236 is presently controlling battery voltage, servo target 306 may correspond to a battery rail voltage 222 that is higher than the desired battery voltage by an amount equal to a resistive voltage drop between the charger 202 side and the battery 208 side. Alternatively, in an embodiment, rather than representing a target voltage, servo target 306 may represent a different target parameter. For example, servo target 306 may correspond to a target current to feed to battery 208 during charging. Similarly, servo target 306 may correspond to a target duty cycle for the power converter 224 to keep the lowest error on the battery 208 side at zero. Thus, servo target 306 may be a control code (e.g., either “increment power up” or “increment power down”), a target voltage value, a target current value, etc., which may be used as a set point for the second feedback control loop process. Ultimately, charger controller 216 may control charger 202 based on servo target 306 to charge battery 208 such that battery measurements 303 taken by battery gauge 214 achieve the desired charging profile 302.

In an embodiment, to maintain a low error in the control scheme implemented by battery controller 236 at zero, the only parameter that may require adjustment on the charger 202 side is battery rail voltage 222. Battery rail voltage 222 and battery cell 210 may typically have a net voltage in a direction, either toward battery cell 210, or away from battery cell 210. For example, when battery rail voltage 222 is higher than an open circuit voltage of battery cell 210, current will flow toward battery cell 210, assuming that other components do not block the current flow, e.g., fuses 241 or protective FETs 240 shown in FIG. 2. The amount of current flow will depend on the net voltage amount, and thus, by controlling battery rail voltage 222 to a given value, it is possible to control charging voltage or current to a corresponding value. Accordingly, in an embodiment, charger controller 216 may adjust power converter 224 to control battery rail voltage 222 to maintain battery measurements 303 at the desired levels. More particularly, battery rail voltage 222 may be adjusted to achieve a desired level measured by battery voltage sensor 230 or battery current sensor 232, corresponding to instantaneous target values of charging profile 302.

Charger controller 216 may receive servo target 306 from battery gauge 214 and/or battery controller 236. Charger controller may implement a second feedback control loop process, such as a proportional-integral-derivative (PID) control scheme, to adjust power converter 224 and control power delivered to a terminal of battery 208 based on servo target 306 and feedback measurements taken along a battery rail connected to the terminal. In an embodiment, servo target 306 may correspond to a target voltage for battery rail voltage 222 on the battery rail connected to the terminal of battery 208.

In an embodiment, charger controller 216 implements a PID control scheme similar to the scheme implemented by battery controller 236. That is, charger controller 216 may receive servo target 306 from battery controller 236 as a control set point. Charger controller 216 may also receive measurements from one or more sensors that measure the battery rail. For example, a voltage sensor may measure battery rail voltage 222. More specifically, battery rail voltage 222 measurements may be received by charger controller 216 as a process variable. Accordingly, the set point, i.e., servo target 306, may be compared with the process variable, i.e., battery rail voltage 222, to determine an instantaneous error signal. Subsequently, the error signal may be introduced into a PID controller having one or more of proportional, integral, or derivative components, to output a manipulated variable. More particularly, the manipulated variable may be a control variable to adjust power converter 224 to change a level of conversion of input voltage 218. The manipulated variable may be, for example, a duty cycle parameter for the power converter 224. Accordingly, charger controller 216 may be configured to adjust power converter 224 output to cause battery rail voltage 222 to equal a desired value corresponding to servo target 306. Adjustment of power converter 224 may therefore drive the instantaneous error signal to zero once battery rail voltage 222 equals the desired value set by servo target 306.

Notably, since charging current may be controlled by adjusting battery rail voltage 222, achieving a desired charging current over time, e.g., a constant charging current, according to a given stage of a charging profile 302 may require continuous adjustment of battery rail voltage 222. For example, a constant net voltage between battery rail voltage 222 and battery cell 210 may be necessary over time to cause a constant charging current over time, and thus, as the charge level of battery cell 210 increases, so must battery rail voltage 222 increase to maintain the appropriate net voltage. Accordingly, during constant current stages of a charging profile 302, servo target 306 may be continuously updated to drive battery rail voltage 222 to an ever-higher target rail voltage value to compensate for the increasing voltage measured at the battery cell 210. Similarly, during constant voltage stages of a charging profile 302, servo target 306 may be continuously updated to drive battery rail voltage 222 to an ever-lower target rail voltage value to compensate for decreasing charging current that produces a lower voltage drop between the battery rail and the battery cell 210.

In an embodiment, an operating frequency of the first feedback control loop process implemented by battery controller 236 and the second feedback control loop process implemented by charger controller 216 is different. More particularly, battery controller 236 may operate at a lower bandwidth than charger controller 216. For example, updating of the servo target 306 by battery controller 236 to set a desired charging power for charger controller 216 may require relatively infrequent adjustment, e.g., on the order of once every one to ten seconds. Thus, battery controller 236 may implement the first feedback control loop process as a PID control algorithm that calculates and/or communicates servo target 306 once per second. Accordingly, the target value for controlling battery rail voltage 222 based on servo target 306 may be changed or updated relatively infrequently. However, charger controller 216 may implement second feedback control loop process to adjust power converter 224 on a more frequent basis. For example, charger controller 216 may implement the second feedback control loop process as a PID control algorithm that calculates a manipulated variable, e.g., a duty cycle, to adjust power converter 224 and control power output along the battery rail on the order of a few hundred to a few hundred thousand times per second, and is typically implemented as an analog feedback controller.

Since changes to servo target 306 by battery controller 236 may occur relatively infrequently as compared to adjustments to the manipulated variable made by charger controller 216, overshoot by charger controller 216 should be avoided. Accordingly, the PID control scheme implemented by battery controller 236 may be modified to omit either the proportional or derivative terms. That is, the PID control scheme may include zero-value proportional gain and derivative gain terms. Thus, the PID control algorithm for calculating servo target 306 may be implemented as an iterative formula based upon an instantaneous lowest error for a variable of interest being multiplied by an integral gain and then added to a previous servo target 306, i.e., the servo target 306 calculated approximately one second earlier.

When an iterative formula having integral control action only is relied upon to implement a PID control scheme, special considerations are required for the integral term initialization. A logical initial integral term value at the beginning of charging would be the measured battery voltage, i.e., the sum of battery bank voltages measured by one or more battery voltage sensors 230. This may allow charger 202 to begin in a state with the same current that exists prior to charging.

Using a non-zero value for the integral gain in the PID control scheme may also require special considerations to prevent integral wind-up when the battery rail voltage 222 is not controlled by the second feedback control loop process implemented by the charger controller 216. The high-bandwidth operation of the second feedback control loop process that adjusts the power converter duty cycle is limited either by the input voltage 218 of power converter 224, the input current 220 of power converter 224, feedback voltage such as the measured battery rail voltage 222, or the duty cycle of the power converter 224, which may approach 0% or 100% when far away from any of the other limits. For example, if power supply 204 is unable to provide input voltage 218 or input current 220 required to generate battery rail voltage 222 corresponding to servo target 306, the deficient power may cause the PID algorithm of battery controller 236 to increase servo target 306 and demand that more voltage be provided. However, since power converter 224 would also not be able to achieve the higher requested battery rail voltage 222, battery controller 236 may continue to escalate servo target 306, causing integral wind-up. In an embodiment, to prevent integral wind-up, charger controller 216 informs battery controller 236 about whether the second feedback control loop process is limited by battery rail voltage 222, or not. For example, charger controller 216 may provide a notification 308 to battery controller 236 when any limit other than battery rail voltage, e.g., input voltage 218, input current 220, or duty cycle of power converter 224, limits the PID control scheme implemented by charger controller 216. In such case, battery controller 236 may recognize that the conditions for integral wind-up are present, and may discontinue updating or communicating servo target 306 until the integral wind-up conditions cease. More particularly, once the second feedback control loop process implemented by charger controller 216 is again limited by battery rail voltage 222, charger controller 216 may send a notification 308 to battery controller 236 requesting a new servo target 306. Thus, notifications 308 may be communicated from charger controller 216 to battery controller 236 to regulate the updating of servo target 306 for use as a set point in the second feedback control loop process and to avoid integral wind-up.

In an embodiment, decoupling the operating interval of charger controller 216 and battery controller 236 allows for battery 208 components to be designed for accuracy and charger 202 components to be designed for precision. Battery controller 236 may repeatedly output servo target 306 at a relatively low rate based on accurate measurements 303 taken within battery 208 directly at battery cell 210. Thus, the battery sensors, battery gauge 214, and battery controller 236 may be selected to optimize the accuracy of battery measurements 303 and servo target 306 calculations. By contrast, charger controller 216 may repeatedly adjust power converter 224 to control battery rail voltage 222 to a target voltage corresponding to servo target 306 at a high rate. Since the accuracy of battery measurements 303 and the servo target 306 may be provided by battery gauge 214 and battery controller 236, respectively, charger controller 216 may be designed to measure battery rail voltage 222 with high precision, rather than high accuracy. That is, any measurement inaccuracy in charger 202 may be compensated for by battery 208 since, for example, if charger controller 216 measurement of battery rail voltage 222 is inaccurately offset by an amount, battery controller 236 may compensate by altering servo target 306 opposite to the offset to ensure that the actual voltage measured at the battery cell 210 by battery voltage sensor 230 is driven toward the target level of charging profile 302.

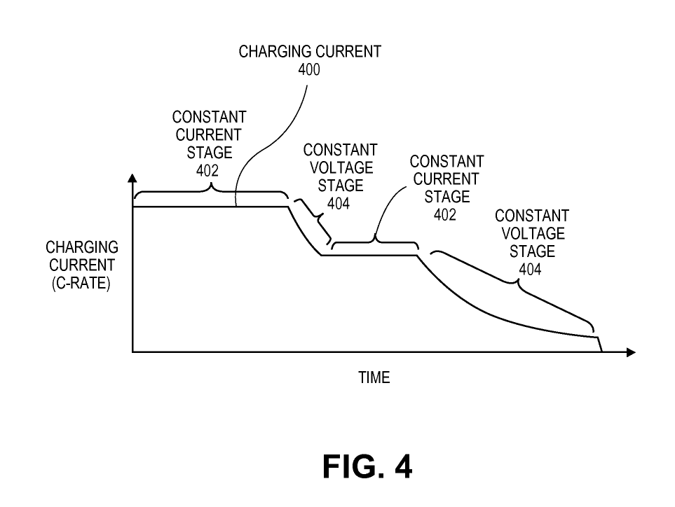

Referring to FIG. 4, a graphical view of a battery charging system current versus time is shown in accordance with an embodiment of the invention. In an embodiment, a charging current 400 delivered from charger 202 to battery 208 along battery voltage rail has a profile with one or more constant current stages 402 and one or more constant voltage stages 404. The charging current 400 may be measured by battery current sensor 232 and fed to battery controller 236 for updating servo target 306. More particularly, during the constant current stages 402, charging current 400 may represent the lowest error, i.e., the measured value may equal the target value of charging profile 302. Thus, servo target 306 may be updated based on error calculations associated with charging current until the constant voltage stages 404 are encountered when battery voltage equals the target value of charging profile and the control scheme switches to controlling battery voltage and implements a new target value for battery current based on charging profile 302.

As shown in FIG. 4, charging current over time may be controlled using “C-rate” units. A C-rate is a unit of measure that expresses how much current can be pulled out of a battery such that the battery fully discharges in one hour from a state of full charge. For example, when a battery is new, it may be a 10 amp-hour, but when the battery is older, it may have degraded to become a 5 amp-hour battery. Accordingly, when new, a one C-rate charging level would imply that the application of 10 amps for one hour would charge the battery fully, but when older, a one C-rate charging level would imply that the application of only 5 amps for one hour would charge the battery fully. Thus, by charging a battery based on C-rate, rather than amps, older batteries may be treated proportional to their capacity, rather than being stressed by more vigorous charging that is more appropriate for newer batteries. In the control scheme described above, battery controller 236 may calculate and store information related to battery 208, such as battery capacity, time to discharge, etc., as battery 208 ages. Thus, battery controller 236 may combine this knowledge with measurements taken by battery sensors to calculate a servo target 306 that controls the charging process using C-rate units, rather than amperage. By doing so, the charging process may provide for longer battery lifetimes.

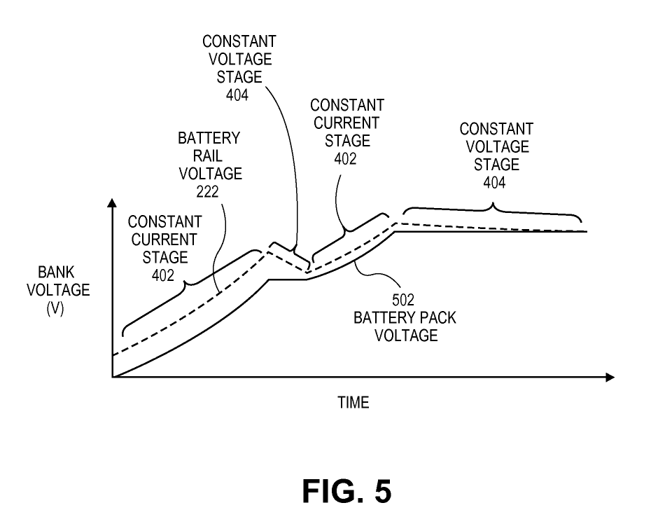

Referring to FIG. 5, a graphical view of a battery charging system voltage versus time is shown in accordance with an embodiment of the invention. The figure depicts battery rail voltage 222 controlled by charger controller 216 as a dotted line. The figure depicts battery pack voltage 502 measured within battery 208 by one or more battery voltage sensor 230 as a solid line. More particularly, over time multiple constant current stages 402 and constant voltage stages 404 may be implemented as part of a charging profile 302 to charge battery 208 and bring battery pack voltage 502 up to a full charge state. As described above, the constant current stages 402 may correspond to periods of time during which battery current represents the lowest error in the battery controller 236 control scheme and constant voltage stages 404 may correspond to periods of time during which battery voltage represents the lowest error in the battery controller 236 control scheme. At any point in time, the battery rail voltage 222 may be higher than the voltage 502 measured at the battery pack due to resistive voltage drops across, e.g., one or more fuse 241 and/or protective FET 240. Consequently, during constant voltage phases 404 of a charging profile 302, the battery rail voltage 222 may be constantly dropping as the charging current drops (see FIG. 4) to maintain constant voltage 502 at the battery cell 210.

By determining servo target 306 based on measurements taken across each individual battery bank in a battery pack of battery 208, resistive voltage drop is naturally accounted for in the measurement 502 at the battery banks and in the process control. That is, the voltage measured within battery 208 at a first battery bank and at a second battery bank does not include resistive voltage drops across connectors and safety components that exist between the battery banks and battery rail voltage 222. Consequently, the charging time of battery 208 may improve during the constant-voltage stages of charging by controlling the voltages measured at the battery bank to be constant instead of keeping measurements of battery rail voltage 222 constant. Doing so may eliminate the need to estimate resistive voltage drops when controlling charger 202. Preliminary tests indicate that charging time may be on the order of 20 minutes faster using battery charging system 200 having the closed-loop control described above, as compared to a typical battery charging system.

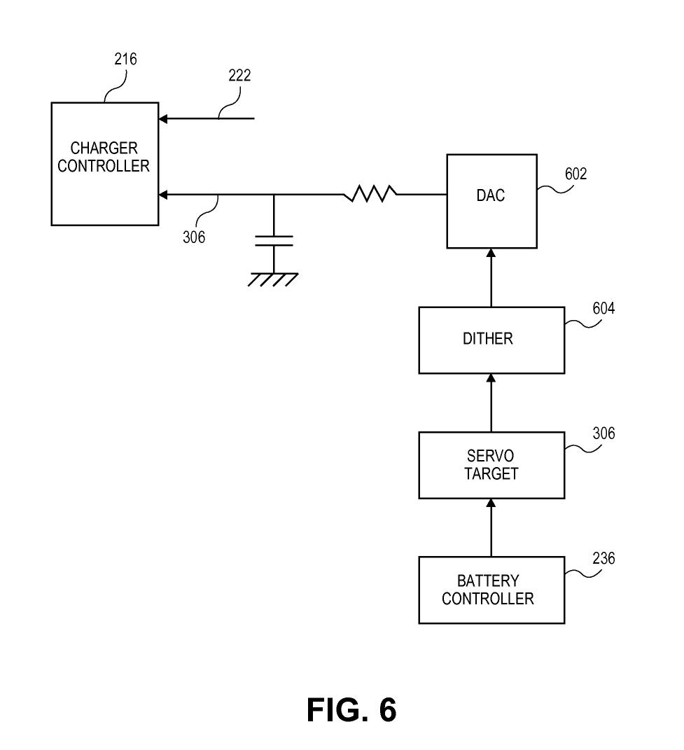

Referring to FIG. 6, a schematic view of a battery charging system having a digital-to-analog converter is shown in accordance with an embodiment of the invention. Charger 202 may include a digital-to-analog converter (DAC) to set voltage targets for power converter 224. More particularly, charger controller 216 may include a DAC that receives servo target 306 as a digital DAC code and converts the digital input to an analog voltage target. The analog target may be provided to circuitry that adjusts an output of power converter 224 that supplies power to the battery rail. Thus, a DAC 602 may be incorporated in, e.g., charger 202, to transform a digital servo target 306 received from battery controller 236 into an analog servo target 306 for use by charger controller 236 to adjust power converter 224 to achieve the desired battery rail voltage 222. DAC 602 may be resolution-limited, e.g., may only have a resolution of about 16 mV, which is a typical resolution across a 5 V operating range using a DAC incorporating resistor ladders. Since the target voltage may be updated only once per second, however, the analog output of the DAC can be filtered and the DAC value can be dithered around the desired digital servo target 306.

Digital servo target 306 may be provided by battery controller 236 as a high-resolution value, e.g., a 16-bit target value, periodically at a frequency corresponding to the operational bandwidth of the first feedback control loop process, e.g., once per second. A DAC 602 with lower resolution than the digital servo target 306, e.g., an 8-bit DAC, may be connected to the battery controller 236 to receive the servo target 306 as an input. However, the digital servo target 306 may be dithered by dithering electronics 604 before being fed to DAC 602. The DAC 602 analog output may then be passed through a resistor-capacitor circuit 606 to obtain an analog servo target 306. Analog servo target 306 may be fed into charger controller 236 for use in the second feedback control loop process for comparison against, e.g., measured values of battery rail voltage 222 or another feedback measurement such as current or duty cycle. The analog servo target 306 may thus be obtained with considerably higher precision than is allowed by DAC 602 without dithering.

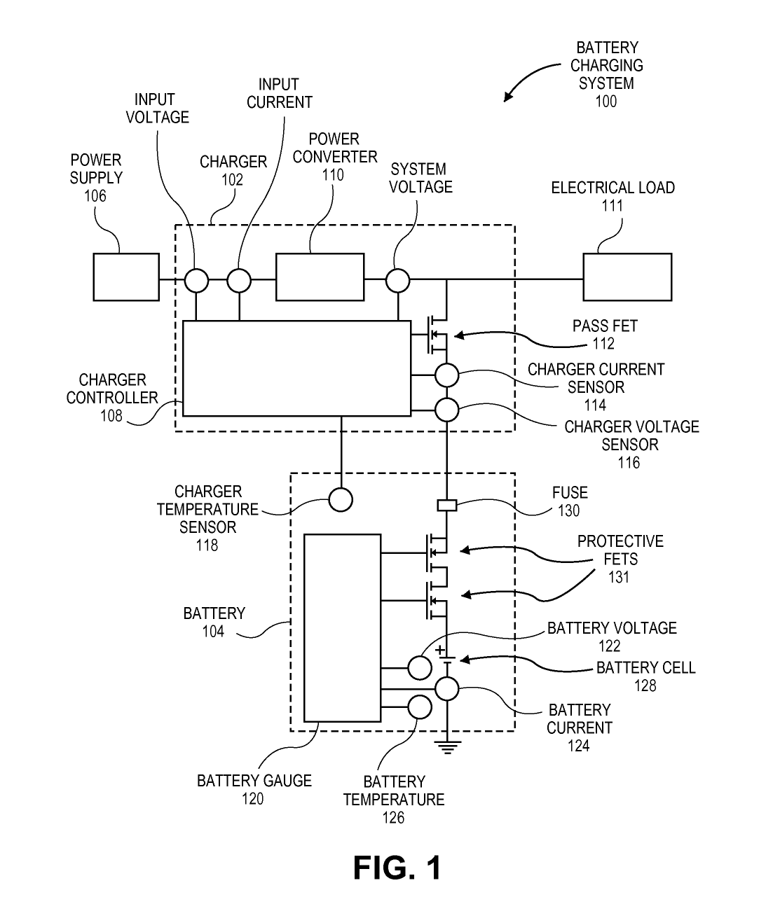

In an embodiment, battery charging system 200 does not require a pass FET along battery voltage rail to disable charging once battery 208 has reached a fully charged state. Instead, a protective FET 240, such as charge FET 242 shown above in FIG. 2, may be used to disable charging. When battery 208 is fully charged as indicated by battery measurements 303, battery controller 236 can turn off charge FET 242 and provide a servo target 306 to charger controller 216 that is some offset higher than the battery voltage measured by battery voltage sensor 230. Thus, power converter 224 may be adjusted by charger controller 216 to control battery rail voltage 222 to a voltage that will prevent discharge from battery cell 210, but will also not charge battery 208 further, since charge FET 242 will block charging current flow toward battery cell 210. By using charge FET 242 to disable charging, a pass FET 112 may not be required in charger 202, thereby reducing system component redundancy. Eliminating a pass FET in battery charging system 200 may also improve battery 208 runtime since there may be less path resistance and power dissipation between battery 208 and other electronic components of electronic device 206 during battery 208 discharges. Nonetheless, in an embodiment, battery controller 236 may be unable to directly control charge FET 242 to disable charging, and thus, a pass FET similar to pass FET 112 of FIG. 1 may be implemented in charger 202 to disable charging.

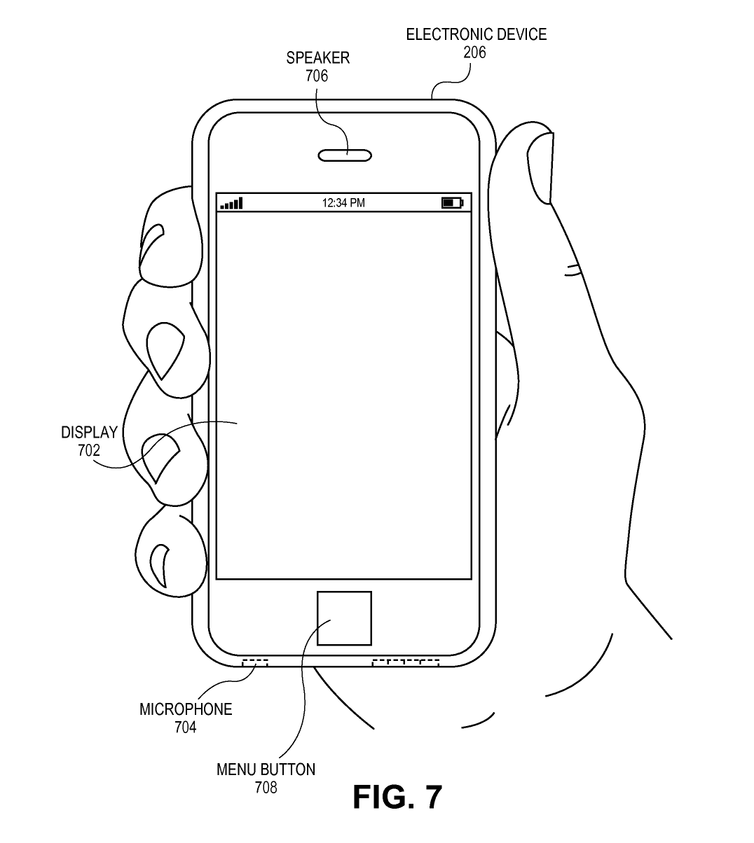

Referring to FIG. 7, a pictorial view of an electronic device having a battery charging system is shown in accordance with an embodiment of the invention. Electronic device 206 may be an iPhone™ device by Apple Inc. of Cupertino, Calif. Alternatively, it could be any other multi-function device having a touchscreen display 702 or other manual user data input device. For example, electronic device 206 may be any portable or stationary device or apparatus incorporating a battery, such as a laptop computer, a tablet computer, an uninterruptible power supply, etc. Electronic device 206 may include various capabilities to allow the user to access features involving, for example, calls, text messages, voicemail, e-mail, the Internet, scheduling, photos, and music, as shown on display 702. Icons representing such applications may appear on a main menu as shown on display 702. Electronic device 206 may also include hardware to facilitate such capabilities. For example, an integrated microphone 704 may pick up the voice of its user during a call, and a speaker 706 may deliver a far-end voice to the near-end user during the call. A menu button 708 may allow the user to return a graphical user interface running in the electronic device 206 to a main menu, as shown, from anywhere within a hierarchical menu tree. Other conventional features are not shown but may of course be included in electronic device 206.

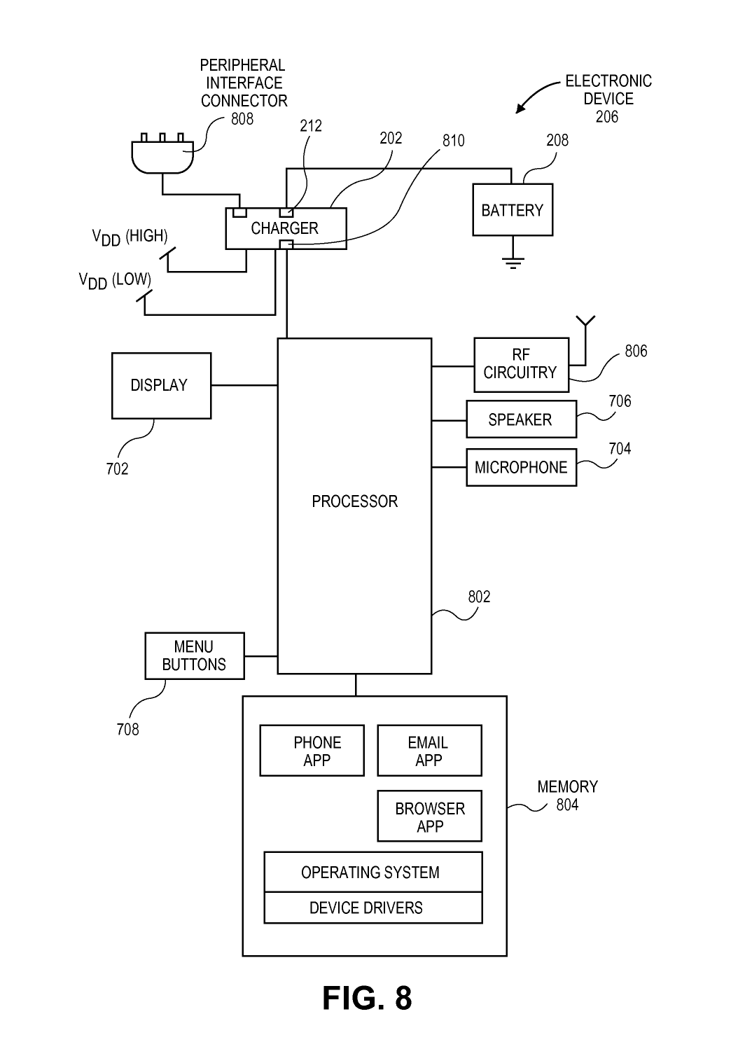

Referring to FIG. 8, a schematic view of an electronic device having a battery charging system is shown in accordance with an embodiment of the invention. As described above, electronic device 206 may be one of several types of portable or stationary devices or apparatuses with circuitry suited to specific functionality, and thus, the circuitry diagrammed in FIG. 8 is provided by way of example and not limitation. Electronic device 206 may include a processor 802 that executes instructions to carry out the different functions and capabilities described above. The instructions may be retrieved from local memory 804, and may be in the form of an operating system program having device drivers, as well as one or more application programs that run on top of the operating system, to perform the different functions introduced above, e.g., phone or telephony, e-mail, and Internet browsing. The latter may be achieved using a wireless link enabled by RF circuitry 806 and its associated RF antenna, to yield a wireless local area network (WLAN) link to a nearby WLAN access point, or a cellular data link to a cellular telephone communications network base station.

Electronic device 206 may have battery 208 integrated within an external housing, and battery 208 may be connected to charger 202 through connector 212. Charger 202 may be connected to a computer peripheral interface connector 808 that allows a pluggable connection with a separate power supply 204, e.g., a USB compatible host such as an AC wall power adapter or a laptop or desktop computer for example. Charger 202 may be connected to processor 802 via communication interface circuitry 810. In an embodiment, battery controller 236 may be incorporated directly on processor 802, and thus, communication interface circuitry 810 may communicate battery measurements from battery 208 to processor 802, and servo target 306 from processor 802 to charger 202. Power supply 204 voltages V_{dd}(high) and V_{dd}(low) are available from charger 202 along a system voltage rail to power most of the components of electronic device 206 shown in the block diagram, e.g., display 702, microphone 704, and speaker 706.

In the foregoing specification, the invention has been described with reference to specific exemplary embodiments thereof. It will be evident that various modifications may be made thereto without departing from the broader spirit and scope of the invention as set forth in the following claims. The specification and drawings are, accordingly, to be regarded in an illustrative sense rather than a restrictive sense.

1. (canceled)

2. A battery charging system, comprising:
a battery controller configured to determine a servo target based on a lower of a current error and a voltage error; and
a charging controller configured to adjust operation of a power converter based on the servo target,
wherein the current error is determined by the battery controller based on a battery current and a target current, and responsive to the battery current approaching the target current, the target current is updated by a charging profile selector with a new current value, and
wherein the voltage error is determined by the battery controller based on a battery voltage and a target voltage, and responsive to the battery voltage approaching the target voltage, the target voltage is updated by the charging profile selector with a new voltage value.

3. The battery charging system of claim 2,
wherein the battery controller is configured to determine the servo target at a first rate,
wherein the charging controller is configured to adjust operation of the power converter at a second rate.

4. The battery charging system of claim 2, further comprising a digital-to-analog converter (DAC) configured to receive a digital signal, representative of the servo target, from the battery controller and provide an analog signal, representative of a control target, to the charging controller.

5. The battery charging system of claim 4, wherein responsive to the DAC being a low-resolution DAC, the digital signal is dithered around the servo target by the battery controller and the analog signal is filtered by a low-pass filter.

6. The battery charging system of claim 2,
wherein the charging controller comprises a proportional-integral-derivative (PID) control and is further configured to provide a notification to the battery controller responsive to a wind-up in the PID control, and
wherein the battery controller is further configured to clamp the servo target responsive to the notification.

7. The battery charging system of claim 2, further comprising a battery gauge configured to provide metrics representative of the battery current and the battery voltage to the battery controller and the charging profile selector.

8. The battery charging system of claim 2, wherein adjusting operation of the power converter comprises adjusting one or more of: an output voltage, an output current, and a duty cycle of the power converter.

9. A method for managing a battery charging system, comprising:
determining a servo target based on a lower of a current error and a voltage error by a battery controller; and
adjusting operation of a power converter based on the servo target by a charging controller,
wherein the current error is determined by the battery controller based on a battery current and a target current, and responsive to the battery current approaching the target current, the target current is updated by a charging profile selector with a new current value, and
wherein the voltage error is determined by the battery controller based on a battery voltage and a target voltage, and responsive to the battery voltage approaching the target voltage, the target voltage is updated by the charging profile selector with a new voltage value.

10. The method of claim 8,
wherein determining the servo target is performed at a first rate,
wherein adjusting operation of the power converter is performed at a second rate.

11. The method of claim 8, further comprising providing a digital signal, representative of the servo target, from the battery controller to a digital-to-analog converter (DAC) and providing an analog signal, representative of a control target, from the DAC to the charging controller.

12. The method of claim 11, wherein responsive to the DAC being a low-resolution DAC, dithering the digital signal around the servo target by the battery controller and filtering the analog signal by a low-pass filter.

13. The method of claim 8, further comprising:
providing a notification from the charger controller to the battery controller responsive to a wind-up in a proportional-integral-derivative (PID) control of the charging controller; and
clamping the servo target by the battery controller responsive to the notification.

14. The method of claim 8, further comprising providing metrics representative of the battery current and the battery voltage from a battery gauge to the battery controller and the charging profile selector.

15. The method of claim 8, wherein adjusting operation of the power converter comprises adjusting one or more of: an output voltage, an output current, and a duty cycle of the power converter.

16. A non-transitory program storage device comprising instructions stored thereon to cause one or more processors to:
determine a servo target based on a lower of a current error and a voltage error; and
adjust operation of a power converter based on the servo target,
wherein the current error is determined based on a battery current and a target current, and responsive to the battery current approaching the target current, the target current is updated with a new current value, and
wherein the voltage error is determined based on a battery voltage and a target voltage, and responsive to the battery voltage approaching the target voltage, the target voltage is updated with a new voltage value.

17. The non-transitory program storage device of claim 16,
wherein the servo target is determined at a first rate,
wherein operation of the power converter is adjusted at a second rate.

18. The non-transitory program storage device of claim 16, further comprising instructions to cause the one or more processors to provide a digital signal, representative of the servo target, to a digital-to-analog converter (DAC) and to receive an analog signal, representative of a control target, from the DAC.

19. The non-transitory program storage device of claim 18, further comprising instructions to cause the one or more processors to dither the digital signal around the servo target responsive to the DAC being a low-resolution DAC, wherein the analog signal from the DAC is filtered by a low-pass filter.

20. The non-transitory program storage device of claim 16, further comprising instructions to cause the one or more processors to:
adjust operation of the power converter based on a proportional-integral-derivative (PID) control; and
clamp the servo target responsive to a notification of a wind-up in the PID control.

21. The non-transitory program storage device of claim 16, wherein adjusting operating of the power converter comprises adjusting one or more of: an output voltage, an output current, and a duty cycle of the power converter.
